(19) United States
(12) Patent Application Publication
(10) Pub. No.: US 2024/0171841 A1
(43) Pub. Date: May 23, 2024

(54) CAMERA MODULE, IMAGE ACQUISITION MODULE, AND PROCESSING METHOD FOR BASE OF IMAGE ACQUISITION MODULE

(71) Applicant: SHENZHEN JSL ELECTRONICS CORPORATION LIMITED, Shenzhen, Guangdong (CN)

(72) Inventor: Dong LI, Shenzhen (CN)

(21) Appl. No.: 18/550,251

(22) PCT Filed: Aug. 29, 2022
(86) PCT No.: PCT/CN2022/115442

§ 371 Date: Sep. 12, 2023

(30) Foreign Application Priority Data
Aug. 3, 2021 (CN) 202110885902.8
May 12, 2022 (CN) 202210515002.9

(51) Int. Cl. H04N 23/55; H04N 23/54

(52) U.S. Cl. CPC H04N 23/55; H04N 23/54

(57) ABSTRACT

The present invention relates to a camera module, an image acquisition module, and a processing method for a base of an image acquisition module. The processing method for the base comprises the following steps: providing a conductor; placing the conductor in a mold cavity and injecting molten plastic into the mold cavity to form the base, wherein one side of the base is used for assembling a lens holder, and the other side is used for electrically connecting and mounting an image sensor by means of the conductor.

### CROSS-REFERENCE TO RELATED APPLICATIONS

This application is an U.S. national phase application under 35 U.S.C. § 371 based upon international patent application No. PCT/CN2022/115442, filed on Aug. 29, 2022, which itself claims priority to Chinese patent application No. 2022105150029 filed on May 12, 2022, and Chinese patent application No. 2021108859028 filed on Aug. 3, 2021. The contents of the above identified applications are hereby incorporated herein in their entireties by reference.

### TECHNICAL FIELD

The present disclosure relates to the technical field of optoelectronic equipment, in particular to a camera module, an image acquisition module and a processing method of a base thereof.

### BACKGROUND

In related technology, during the processing of a camera module, FPC (Flexible Printed Circuit) is generally used as a substrate, and electronic components such as resistors, capacitors, connectors, driver or storage chips, etc. are mounted on a surface of the substrate and fixed by welding, then an image sensor is mounted on the substrate through a special packaging equipment, and an electrical connection between the image sensor and the substrate is achieved by gold wires or solder balls, then a filter, a lens holder, etc. are assembled to the substrate to obtain the camera module.

However, a flatness of the surface of the FPC is generally poor. When the image sensor, the lens holder, and other structures are assembled to the FPC as the substrate, an assembly accuracy of the camera module is difficult to control and the defective rate is high.

### SUMMARY

Accordingly, it is necessary to provide a camera module, an image acquisition module and a processing method of a base thereof to improve yield of product.

A processing method of a base of an image acquisition module includes the following steps of: providing a conductor; placing the conductor in a mold cavity and injecting molten plastic into the mold cavity to form the base, wherein one side of the base is configured to assemble a lens holder, and the other side of the base is configured to electrically connect and mount an image sensor through the conductor.

In one of the embodiments, the processing method further includes: injecting solder paste into the base, and attaching electronic components on the base, the electronic components including at least a resistor and a capacitor; and reflow soldering, so that the electronic components are electrically connected to the conductor through the solder paste.

In one of the embodiments, the step of providing the conductor includes: die-cutting and bending a copper foil into a wire substrate.

In one of the embodiments, after the step of die-cutting and bending the copper foil into the wire substrate, the method further includes: forming a plating layer on a surface of the wire substrate to obtain the conductor, and a material of the plating layer includes at least nickel and gold.

A processing method of a base of an image acquisition module includes the following steps of: providing a conductor; integrally molding the conductor and a plastic into the base, wherein one side of the base is configured to assemble a lens holder, and the other side of the base is configured to electrically connect and mount an image sensor through the conductor.

A processing method of an image acquisition module includes the following steps of: providing a base, wherein the base includes a base body and a conductor injection-molded on the base body; and assembling an image sensor to the base, and electrically connecting the image sensor to the conductor.

In one of the embodiments, prior to the step of assembling the image sensor to the base, the processing method further includes: providing conductive particles on the image sensor, wherein the conductive particles are configured to achieve an electrical connection between the image sensor and the conductor.

In one of the embodiments, the step of assembling the image sensor to the base includes: attaching the image sensor provided with the conductive particles to the base using a flip-chip packaging process.

In one of the embodiments, the step of providing the conductive particles on the image sensor includes any of the following solutions: providing the conductive particles on the image sensor using a gold wire ball welding machine; providing the conductive particles on the image sensor using a laser solder ball welding machine.

In one of the embodiments, the base is manufactured by any one of the processing methods mentioned above.

A processing method of an image acquisition module includes the following steps of: providing a base, wherein the base includes a base body and a conductor integrally formed on the base body; and assembling an image sensor to the base, and electrically connecting the image sensor to the conductor.

A processing method of a camera module includes the following steps of: providing an image acquisition module, wherein the image acquisition module includes a base, a conductor injection-molded on the base, and an image sensor provided on one side of the base and electrically connected to the conductor, and providing a lens holder, and connecting the lens holder to the other side of the base.

In one of the embodiments, the image acquisition module is manufactured by any one of the above-mentioned processing methods mentioned above.

In one of the embodiments, the base has a through hole, after the step of injection molding the conductor into the base and prior to the step of assembling the lens holder to the base, the processing method further includes: assembling a filter on the base wherein an end of the through hole is covered by the filter, and the other, and the other opposite end of the through hole is configured to cover the image sensor.

In one of the embodiments, the base has a first mounting groove and a second mounting groove, the first mounting groove is located on a side of the base and is in communication with the through hole, the first mounting groove is configured to accommodate the filter, the second mounting groove is located on the other opposite side of the base and is in communication with the through hole, and the second mounting groove is configured to accommodate the image sensor.

In one of the embodiments, the image acquisition module further includes an electronic component, solder paste is injected into the base and the electronic component is electrically connected to the conductor by means of solder paste through reflow soldering, a side of the base where the image sensor is located has a second mounting groove and a third mounting groove spaced apart, the second mounting groove is configured to accommodate the image sensor, and the third mounting groove is configured to accommodate the electronic component.

According to the base, image acquisition module and camera module prepared by the processing method, since the conductor electrically connected to the image sensor is injection-molded on the base, the lens holder and the image sensor can be assembled on the base. Compared with the FPC, the base has stronger structural rigidity, and a surface flatness, a position accuracy, etc. of the base can be easily ensured. When the image sensor and the lens holder are assembled on the base, higher assembly accuracy can be obtained. Compared with the structure in which the image sensor is packaged on the FPC and the lens holder is stacked on the FPC in the related art, the above-mentioned image acquisition module has a higher integration, which can reduce the investment in high-precision production equipment, and has fewer production processes, lower quality control difficulties and lower costs. Since the image sensor is electrically connected to the conductor that is injection molded on the base, this configuration simplifies the assembly and electrical connection process of the image sensor and the base, and can ensure the reliability of the electrical connection between the image sensor and the base. The conductor may be made of lower-cost materials such as the copper foil. Compared with the high-purity gold wire of FPC, the conductor has better structural stability and lower cost, and the reliability of the electrical connection of the image sensor can be ensured.

### BRIEF DESCRIPTION OF THE DRAWINGS

In order to illustrate the embodiments of the present disclosure more clearly, the drawings used in the embodiments will be described briefly. Apparently, the following described drawings are merely for the embodiments of the present disclosure, and other drawings can be derived by those of ordinary skill in the art without any creative effort.

FIG. 1 is a schematic view of a camera module in the related art.

FIG. 2 is a schematic view of another camera module in the related art.

FIG. 3 is a schematic diagram of a processing method of an image acquisition module according to an embodiment.

FIG. 4 is a flowchart of a processing method of an image acquisition module according to an embodiment.

FIG. 5 is an exploded view of a camera module according to an embodiment.

FIG. 6 is a bottom view of an image acquisition module according to an embodiment.

FIG. 7 is a schematic diagram of a processing method of an image acquisition module according to another embodiment.

FIG. 8 is a cross-sectional view of a portion of an image acquisition module according to an embodiment.

FIG. 9 is a top view of an image acquisition module according to an embodiment.

FIG. 10 is a cross-sectional view of another portion of an image acquisition module according to an embodiment.

FIG. 11 is a schematic view of a camera module according to an embodiment.

FIG. 12 is a schematic view of the camera module shown in FIG. 11 viewed from another aspect.

### REFERENCE NUMERALS

11, flexible circuit board; 12, image sensor 13, filter;
14, mounting base; 15, lens barrel; 16, connector;
17, electronic component; 18, gold wire; 19, solder ball;
100, lens holder; 110, lens barrel; 120, mounting base;
121, positioning structure; 300, image acquisition module; 301, conductor;
310, base; 311, limiting structure; 320, image sensor;
330, electronic component; 340, conductive particle; 350, filter;
310a, through hole; 310b, first mounting groove; 310c, second mounting groove;
310d, third mounting groove; 30, copper foil.

### DETAILED DESCRIPTION OF THE EMBODIMENTS

In order to facilitate the understanding of the present disclosure, the present disclosure is described more comprehensively below with reference to the relevant accompanying drawings. Preferred embodiments of the present disclosure are shown in the accompanying drawings. However, the present disclosure may be implemented in many different forms and is not limited to the embodiments described herein. On the contrary, the purpose of providing these embodiments is to make the public content of the present disclosure more thoroughly and comprehensively understood.

It should be noted that when an element is referred to as being “fixed to” another element, it can be directly fixed to another element or intervening elements may also be present. When an element is referred to as being “connected to” another element, it can be directly connected to another element or intervening elements may also be present. The terms “vertical”, “horizontal”, “left”, “right”, and similar expressions are used herein for purposes of illustration only.

Unless otherwise defined, all technical and scientific terms used herein have the same meanings as those commonly understood by those skilled in the technical field of the present disclosure. The terms used in the specification of the present disclosure herein are only for the purpose of describing specific embodiments, and are not intended to limit the present disclosure. As used herein, the term “and/or” includes any and all combinations of one or more related listed items.

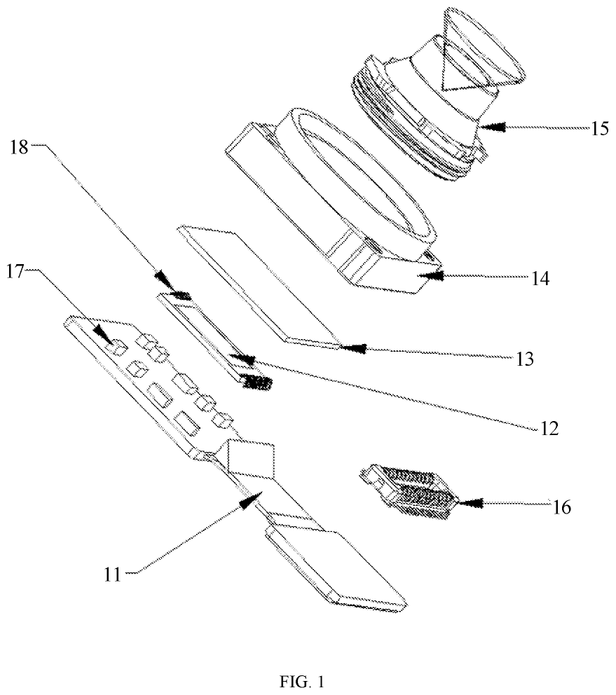

Referring to FIG. 1, in the related art, a COB (Chip on Board) type camera module generally includes a flexible circuit board 11, an image sensor 12, a filter 13, a mounting base 14, a lens barrel 15, and a connector 16. The flexible circuit board 11 is provided with electronic components 17 such as capacitors and resistors. The image sensor 12 is stacked on a side of the flexible circuit board 11 and is electrically connected to the flexible circuit board 11 through gold wires 18. The mounting base 14 is stacked on the flexible circuit board 11 and covers the image sensor 12. The lens barrel 15 is connected to the mounting base 14, and a lens group for converging light to the image sensor 12 is provided in the lens barrel 15. The filter 13 is provided in the mounting base 14 and is located between the lens group and the image sensor 12, and the filter 13 is configured to filter infrared light to improve the quality of shooting. The connector 16 is electrically connected to the flexible circuit board 11, and the camera module can be electrically connected to an external circuit such as a motherboard of a mobile phone through the connector 16, so as to achieve a communication connection between the camera module and the motherboard.

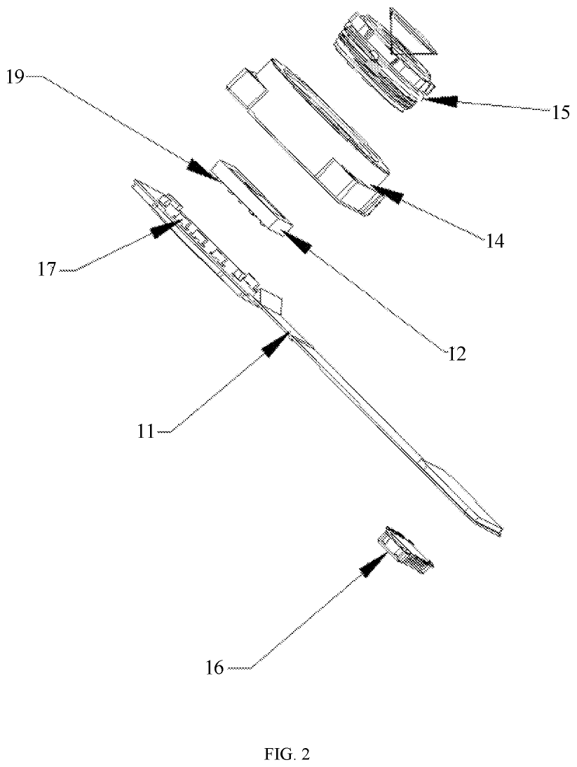

Referring to FIG. 2, in the related art, a CSP (Chip Scale Package) type camera module generally includes a flexible circuit board 11, an image sensor 12, a mounting base 14, a lens barrel 15, and a connector 16. The flexible circuit board 11 is provided with electronic components 17 such as capacitors and resistors. Different from the COP type camera module, the image sensor 12 of the CSP type camera module is generally electrically connected to the flexible circuit board 11 by solder balls 19.

The combination of the lens barrel 15 and the mounting base 14 may be referred to as a lens holder. The lens barrel 15 and the mounting base 14 can be assembled, for example, the lens barrel 15 and the mounting base 14 can be screwed together. The lens barrel 15 can also be integrally formed with the mounting base 14.

With regard to the above COB or CSP type camera module, during the processing process of the camera module, the flexible printed circuit 11 is generally used as a substrate, and the electronic components 17 such as resistors, capacitors, connectors, driver or storage chips, etc. and connector 16 are mounted on a surface of the substrate and fixed by welding, then the image sensor 12 is mounted on the substrate through a special packaging equipment, and an electrical connection between the image sensor 12 and the substrate is achieved by the gold wires 18 or the solder balls 19, then the filter 13, the mounting base 14, and the lens barrel 15, etc. are assembled to the substrate to obtain the camera module.

However, a flatness of the surface of the flexible circuit board 11 is generally poor. When the image sensor 12, the lens holder, and other structures are assembled to the flexible circuit board 11 as the substrate, an assembly accuracy of the camera module is difficult to control and the defective rate is high.

In order to improve the production yield of camera modules, the present disclosure discloses a camera module, an image acquisition module and a processing method of a base thereof. The image acquisition module can be applied to the camera module to improve the production yield of the camera module.

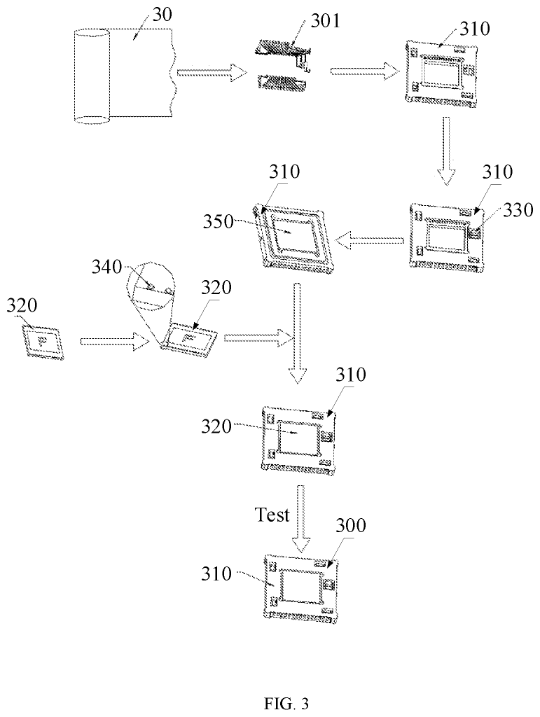

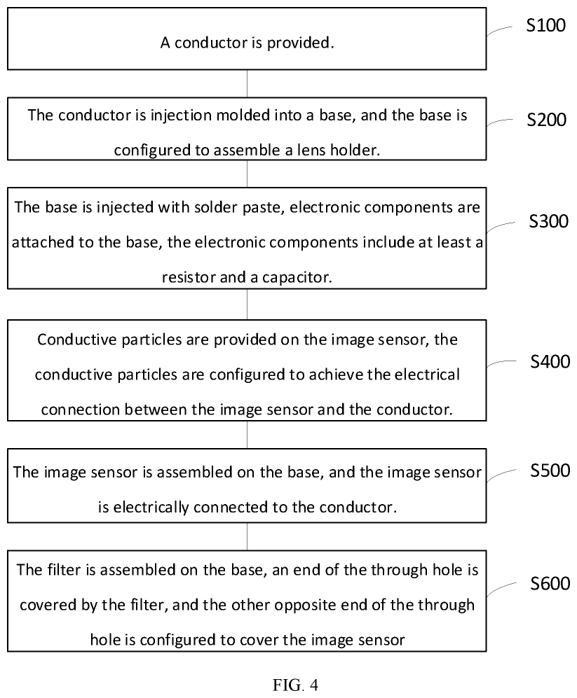

Referring to FIG. 3 and FIG. 4, a processing method of an image acquisition module 300 includes the following steps.

S100, a conductor 301 is provided.

In some embodiments, the conductor 301 uses copper as base material, i.e., as a main part of a conductive circuit, and its surface can be plated with a metal coating to improve surface wear resistance and electrical conductivity. In the embodiment of the present disclosure, the conductor 301 is configured to be electrically connected to the image sensor 320 of the camera module, and can be configured to be electrically connected to external circuit boards such as the motherboards of electronic devices such as mobile phones and tablet computers, so as to achieve a communication connection between the camera module and the external motherboard. When copper is used as the base material of the conductor 301, a cost is relatively low compared with gold wires 18, silver wires, and the like. Certainly, in other embodiments, the base material of the conductor 301 may also be silver wire or other alloy materials.

In the step S100 of providing the conductor 301, specifically, the following steps may be included.

S110: the copper foil 30 is die-cut and bent into a wire substrate.

Referring to FIG. 3, in some embodiments, after punching and bending the copper foil 30 using a cutting die, the wire substrate is obtained. The wire substrate is approximately curved. Two or more wire substrates may be provided. One end of the wire substrate may be configured to be electrically connected to the image sensor 320, and the other end of the wire substrate may be configured to be connected to an external circuit. Certainly, other connection points can be provided between both ends of the wire substrate, and the connection points can be configured to be electrically connected to electronic components 17 of the camera module such as resistors, capacitors, and driver or storage chips, etc., so as to achieve a normal operation of the camera module.

After the step S110 of die-cutting and bending the copper foil 30 into the wire substrate, the following steps may further be included.

S130, a plating layer is formed on a surface of the wire substrate to obtain the conductor 301, and the material of the plating layer includes at least nickel and gold.

The plating layer can improve surface properties of the conductor 301, such as improving a wear resistance and an electrical conductivity of the surface of the conductor 301. In some embodiments, a material of the plating layer may also include tin. Certainly, it should be understood that the plating layer on the surface of the conductor 301 can be omitted.

In some embodiments, the plating layer is formed on the surface of the wire substrate by a spot plating process. The spot plating process is a type of electroplating process in which the plating solution is ejected at high pressure from anode water bladder to a plating area, and metal ions in the plating solution are deposited on the plating area under an action of an electric field to form the plating layer. The accurate plating area can be obtained by the spot plating process, that is, a designated position can be electroplated by the spot plating process.

S200, the conductor 301 is injection molded into a base 310, and the base 310 is configured to assemble a lens holder 100.

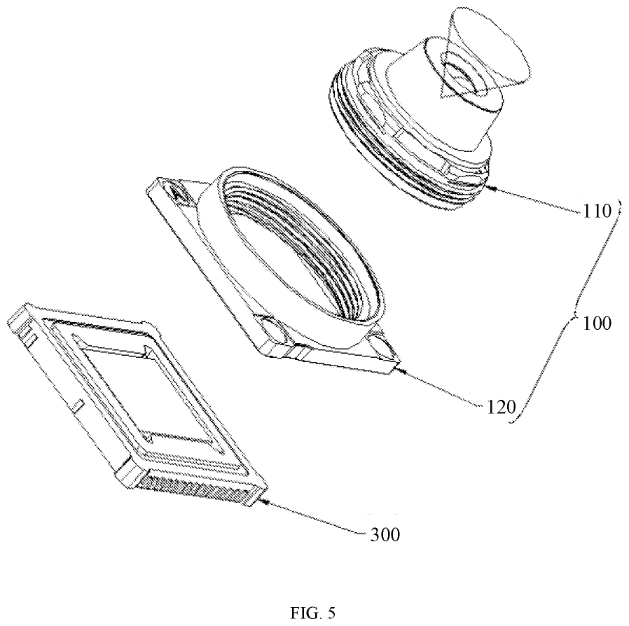

In some embodiments, through an insert molding process, the conductor 301 is placed in a preset mold cavity, then molten plastic is injected into the mold cavity. After the plastic is cooled, the base 310 can be formed. The conductor 301 of the base 310 is wrapped by plastic material. In some embodiments, both ends of the conductor 301 may be exposed from the base 310, so as to facilitate the electrical connection between the conductor 301 and the image sensor 320, and facilitate the electrical connection between the conductor 301 and the external circuit. In other embodiments, the conductor 301 does not need to be exposed from the injection molded base 310, and a part plastic of the base 310 covering the conductor 301 can be removed by melting or other means during the assembly of the image sensor 320 and the conductor 301. The structure of the lens holder 100 configured to be assembled with the base 310 is shown in FIG. 5. The lens holder 100 may include a lens barrel 110 and a mounting base 120 connected to each other. The lens barrel 110 may include a plurality of lens groups configured to converge light, and the mounting base 120 may be configured to assemble with the base 310. In other embodiments, the conductor 301 may be integrally formed on the base 310 in other ways, for example, the conductor 301 may be formed on the base 310 by powder metallurgy or the like.

After the step S200 of injection molding the conductor 301 into the base 310, a step S300 may further be included.

S300, the base 310 is injected with solder paste, electronic components 330 are attached to the base 310, the electronic components 330 include at least a resistor and a capacitor.

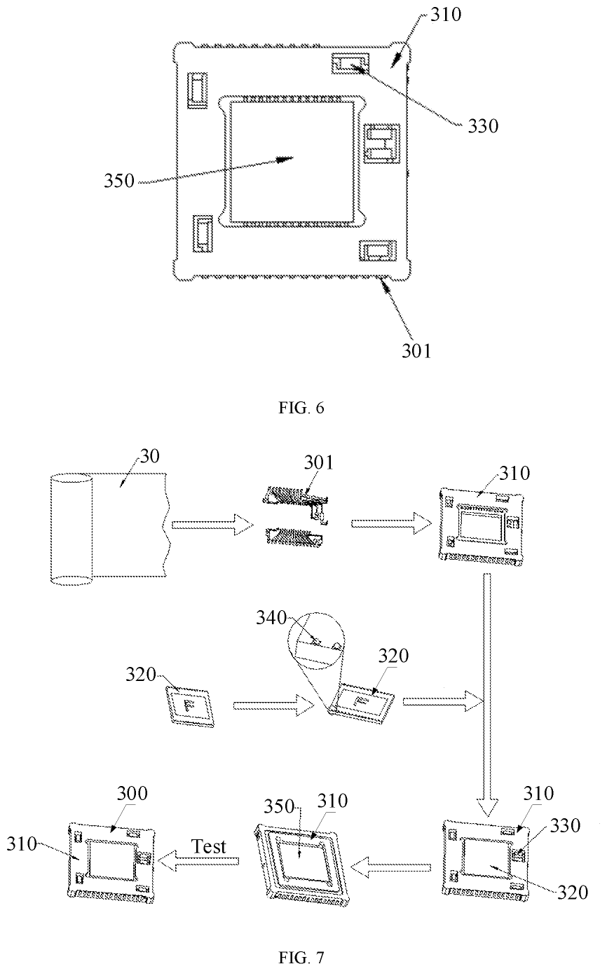

Referring to FIG. 6, in some embodiments, after the base 310 is injected with the solder paste and attached with the electronic components 330, the electronic components 330 can be fixed to the base 310 through reflow soldering, and the reliability of an electrical connection between the electronic components 330 and the conductor 301 can be ensured.

After step S300, step S400 may further be included.

S400, conductive particles 340 are provided on the image sensor 320, the conductive particles 340 are configured to achieve the electrical connection between the image sensor 320 and the conductor 301.

The conductor 301 configured to be electrically connected to the image sensor 320 may be exposed to the base 310, and before the image sensor 320 is assembled on the base 310 and electrically connected to the conductor 301, the conductive particles 340 may be provided at positions of the image sensor 320 for electrical connection, and the conductive particles 340 are configured to achieve the electrical connection between the image sensor 320 and the conductor 301.

The image sensor 320 may also be referred to as a photosensitive chip or a photosensitive element, which can convert received optical signals into electrical signals. An object of the present disclosure is to provide an improved processing method to improve the yield of the base, the image acquisition module, and the camera module, and does not limit the specific type of image sensor 320, so any type of photoelectric conversion device that can capture optical signals and generate electrical signals can be applied to the processing method of the present disclosure. As an example, the image sensor 320 may include, but is not limited to, CCD (Charged Coupled Device), CMOS (Complementary Metal-Oxide Semiconductor), CIS (Contact Image Sensor).

Continuing to refer to FIG. 3, in some embodiments, a gold wire ball welding machine may be used to provide the conductive particles 340 at positions of the image sensor 320 for the electrical connection, that is, the image sensor 320 is planted with gold ball particles, and can be cleaned and dried by centrifugal cleaning, so as to achieve the electrical connection between the image sensor 320 and the conductor 301 through the gold ball particles, and to ensure the reliability of the electrical connection. It should be understood that, in the embodiment, the step S300 and the step S400 may be performed simultaneously, or the step S400 may also be performed prior to the step S300.

In other embodiments, a laser solder ball welding machine may be used to provide conductive particles 340 at positions of the image sensor 320 for electrical connection, that is, solder balls are soldered on the image sensor 320, so as to achieve the electrical connection between the image sensor 320 and the conductor 301 through solder balls and ensure the reliability of the electrical connection. In the embodiment, since tin is used in both the step S300 and the step S400, the step S300 and the step S400 may be performed simultaneously, or the step S400 may be performed prior to the step S300. Referring to FIG. 7, after the base 310 is injected with the solder paste and attached with the electronic components 330 and the solder balls are provided on the image sensor 320, after the image sensor 320 is assembled on the base 310, the reflow soldering is performed together in the following step S500, so that the electronic components 330 form a reliable electrical connection with the image sensor 320 and the conductor 301 of the base 310. This processing method can save processing steps and improve processing efficiency.

S500, the image sensor 320 is assembled on the base 310, and the image sensor 320 is electrically connected to the conductor 301.

After the step S300 and the step S400 are completed, the image sensor 320 can be assembled on the base 310, and corresponding processing (such as reflow soldering, etc.) can be performed to electrically connect the image sensor 320 to the conductor 301 of the base 310. The image sensor 320 can further be electrically connected to the external circuit board through the conductor 301 to enable communication with the external circuit board.

The step S500 of assembling the image sensor 320 on the base 310 may include:

S510, the image sensor 320 provided with the conductive particles 340 is attached to the base 310 using a flip-chip packaging process.

Flip chip is to connect the conductive contacts of the chip to the circuit of the substrate, circuit board and other devices. During the connection process, since bumps of the chip is connected downward, it is called flip chip. Electronic devices manufactured by flip-chip packaging process have high integration, small volume, and high performance.

After the image sensor 320 provided with the conductive particles 340 is attached to the base 310 using the flip-chip packaging process, the image sensor 320 can form a reliable electrical connection with the base 310 after corresponding processing.

After the step S510, the following step S520 may also be performed.

S520, the base 310 attached with the image sensor 320 is tested, and after the base 310 passes the test, the base 310 is filled with adhesive and baked to be cured, so as to obtain the image acquisition module 300.

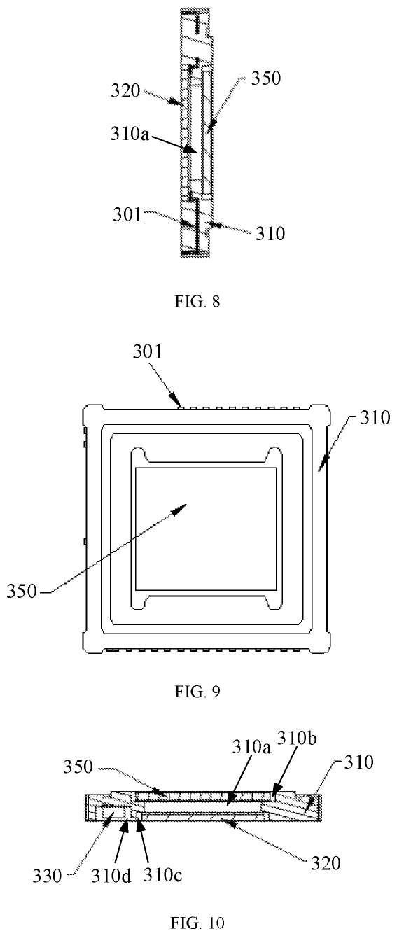

Referring to FIG. 8 and FIG. 9, in some embodiments, the base 310 is provided with a through hole 310a. After the step S200 of injection molding the conductor 301 into the base 310, and prior to the step of assembling the lens holder 100 on the base 310, step S600 may be included.

S600, the filter 350 is assembled on the base 310, an end of the through hole 310a is covered by the filter 350, and the other opposite end of the through hole 310a is configured to cover the image sensor 320.

In some embodiments, at the end of the through hole 310a configured to assemble the filter 350, the filter 350 can be reliably fixed on the base 310 after the operations of painting glue, attaching the filter 350, baking and curing, centrifugal cleaning and drying are sequentially performed.

Further, referring to FIG. 10, in some embodiments, the base 310 has a first mounting groove 310b and a second mounting groove 310c. The first mounting groove 310b is located on a side of the base 310 and is in communication with the through hole 310a, and the first mounting groove 310b is configured to accommodate the filter 350. The second mounting groove 310c is located on an opposite side of the base 310 and is in communication with the through hole 310a, and the second mounting groove 310c is configured to accommodate the image sensor 320. In other words, in the embodiment, the base 310 can respectively define the first mounting groove 310b and the second mounting groove 310c at opposite ends of the through hole 310a. The first mounting groove 310b is configured to mount the filter 350, and the second mounting groove 310c is configured to mount the image sensor 320. The first mounting groove 310b can facilitate the assembly and positioning of the filter 350 on the base 310, and the second mounting groove 310c can facilitate the assembly and positioning of the image sensor 320 on the base 310.

It should be understood that, after the lens holder 100 is assembled to the base 310, the filter 350 is located between the lens group of the lens holder 100 and the image sensor 320. During photographing process, the ambient light passes through the lens holder 100 and the filter 350 in sequence and is incident on the image sensor 320, and then an image is formed on the image sensor 320.

In some embodiments, the filter 350 can be mounted on the base 310 prior to mounting of the image sensor 320, that is, the step S600 can be performed prior to the step S500.

Certainly, in some embodiments, the filter 350 may be omitted, that is, the step S600 may be omitted.

Further, referring to FIG. 10, in some embodiments, a side of the base 310 where the image sensor 320 is located is provided with third mounting grooves 310d spaced apart from the second mounting groove 310c, and the third mounting grooves 310d are configured to accommodate the electronic components 330. Two or more third mounting grooves 310d spaced apart may be provided, and may surround the second mounting groove 310c. One or more electronic components 330 such as resistors, capacitors, etc. can be mounted in each third mounting groove 310d, so that the electronic components 330 are physically isolated from a mounting area of the image sensor 320. With this structure, the mounting area of the image sensor 320 can be reduced, which can effectively prevent dust and other foreign objects from polluting the mounting area of the image sensor 320 during the mounting process of the electronic components, thereby improving the yield of the product.

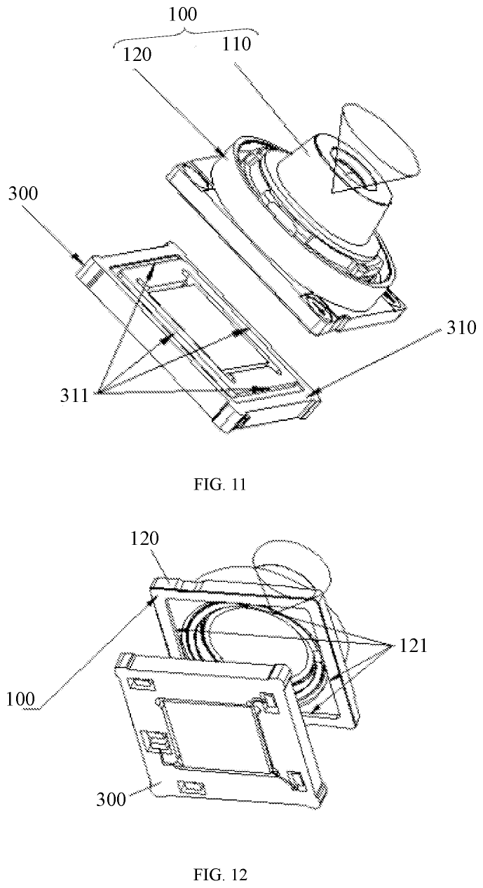

Referring to FIG. 11 and FIG. 12, in some embodiments, after the base 310 is injection molded, a limiting structure 311a may be directly molded or processed on the base 310. The camera module including the lens holder 100 and the image acquisition module 300 is shown in FIG. 11 and FIG. 12. The limiting structure 311a is configured to mount and position the lens holder 100 on the base 310. The lens holder 100 includes a lens barrel 110 and a mounting base 120. The lens barrel 110 is mounted on the base 310 through the mounting base 120, and the mounting base 120 of the camera module may further be provided with a positioning structure 121 configured to cooperate with the limiting structure 311 of the base 310. Exemplary, the limiting structure 311 of the base 310 may be a boss provided on the base 310, and the positioning structure 121 of the mounting base 200 may be a groove adapted to the boss. In some implementations, the mounting base 200 can be assembled to the image acquisition module 300 by an HM (Holder Mount, mounted on the base) equipment, and then positions of the mounting base 110 and the lens barrel 120 of the lens holder 100 on the base 310 is manually adjusted to achieve clear focus of the camera module. In some other embodiments, the lens holder 100 can also be automatically adjusted to achieve clear focus through an AA (Active Alignment) device.

In the above-mentioned image acquisition module 300 prepared by the processing method of the image acquisition module 300, the conductor 301 configured to be electrically connected to the image sensor 320 is injection molded or integrally formed with the base 310, and the lens holder 100 and the image sensor 320 can be assembled on the base 310. Compared with the FPC, the base 310 has stronger structural rigidity, and a surface flatness, a position accuracy, etc. of the base 310 can be easily ensured. When the image sensor 320 and the lens holder 100 are assembled on the base 310, higher assembly accuracy can be obtained. Compared with the structure in which the image sensor 320 is packaged on the FPC and the lens holder 100 is stacked on the FPC in the related art, the above-mentioned image acquisition module 300 has a higher integration, which can reduce the investment in high-precision production equipment, and has fewer production processes, lower quality control difficulties and lower costs. Since the image sensor 320 is electrically connected to the conductor 301 that is injection molded or integrally formed with the base 310, this configuration simplifies the assembly and electrical connection process of the image sensor 320 and the base 310, and can ensure the reliability of the electrical connection between the image sensor 320 and the base 310. The conductor 301 may be made of lower-cost materials such as the copper foil 30. Compared with the high-purity gold wire 18 of FPC, the conductor 301 has better structural stability and lower cost, and the reliability of the electrical connection of the image sensor 320 can be ensured.

In the embodiment of the present disclosure, since the FPC is no longer used as an assembly substrate of the image sensor 320 and the lens holder 100, an expensive nickel-palladium-gold FPC material can be saved, a cost of the product is greatly reduced, a performance is greatly improved, and a higher cost performance and market competitive advantage can be obtained.

Further, since a connection method of the gold wire 18 between the image sensor 320 and the FPC is omitted, when the processing method of the image acquisition module 300 of the present disclosure is adopted, the electronic components (capacitors, resistors, image sensors, etc.) are electrically connected through the conductor 301. The connection method can shorten a circuit length, effectively reduce electrical impedance and signal interference, and further improve the performance and stability of the product.

The processing process of the image acquisition module 300 prepared by the processing method of the image acquisition module 300 of the present disclosure is further optimized, and a large number of assembly processes that need precision equipment or imported equipment to complete are reduced, the equipment input cost and labor cost are greatly reduced, and the production efficiency is greatly improved.

During the production and processing process of the image acquisition module 300, due to the guarantee of the structural rigidity of the base 310 and the improvement of the positional accuracy, the cumulative tolerance of the process can be further reduced, so as to improve the processing and assembly accuracy of the product, so that the yield of the product is greatly improved.

Further, as for the processing method of the image acquisition module 300 provided in the embodiment of the present disclosure, the forming mold of the base 310 can be adaptively adjusted, such that multiple bases 310 or even multiple image acquisition modules 300 can be formed at one time, so as to achieve large-scale, batch and standardized production operations to achieve standardized packaging of the camera module for long-order, long-term, non-line change mass production, so that product stability, yield and production efficiency are greatly improved.

Since the conductor 301 is injection molded or integrally formed with the base 310, the conductor 301 can have a certain structural rigidity, or a male structure for electrical connection can be formed on the base 310 by welding, etc., and the external circuit board only needs to be provided with a corresponding female base structure to achieve the convenient insertion and assembly of the image acquisition module 300 and the external circuit board, so as to shorten the path of electrical connection, and improve the efficiency of assembly and the working performance.

The above-mentioned embodiments do not constitute a limitation on the protection scope of the technical solution. Any modifications, equivalent replacements and improvements made within the spirit and principles of the above-mentioned embodiments shall be included within the protection scope of this technical solution.

The foregoing descriptions are merely specific embodiments of the present invention, but are not intended to limit the protection scope of the present invention. Any variation or replacement readily figured out by a person skilled in the art within the technical scope disclosed in the present invention shall all fall within the protection scope of the present invention.

1. A processing method of a base of an image acquisition module, comprising the following steps of:
providing a conductor;
placing the conductor in a mold cavity and injecting molten plastic into the mold cavity to form the base, wherein one side of the base is configured to assemble a lens holder, and the other side of the base is configured to electrically connect and mount an image sensor through the conductor.

2. The processing method according to claim 1, further comprising:
injecting solder paste into the base, and attaching electronic components on the base, the electronic components comprising at least a resistor and a capacitor; and
reflow soldering, so that the electronic components are electrically connected to the conductor through the solder paste.

3. The processing method according to claim 1, wherein the step of providing the conductor comprises:
die-cutting and bending a copper foil into a wire substrate.

4. The processing method according to claim 3, wherein after the step of die-cutting and bending the copper foil into the wire substrate, the method further comprises: forming a plating layer on a surface of the wire substrate to obtain the conductor, and a material of the plating layer comprising at least nickel and gold.

5. (canceled)

6. A processing method of an image acquisition module, comprising the following steps of:
providing a base, wherein the base comprises a base body and a conductor injection-molded on the base body; and
assembling an image sensor to the base, and electrically connecting the image sensor to the conductor.

7. The processing method according to claim 6, wherein prior to the step of assembling the image sensor to the base, the processing method further comprises:
providing conductive particles on the image sensor, wherein the conductive particles are configured to achieve an electrical connection between the image sensor and the conductor.

8. The processing method according to claim 7, wherein the step of assembling the image sensor to the base comprises:
attaching the image sensor provided with the conductive particles to the base using a flip-chip packaging process.

9. The processing method according to claim 7, wherein the step of providing the conductive particles on the image sensor comprises any of the following solutions:
providing the conductive particles on the image sensor using a gold wire ball welding machine;
providing the conductive particles on the image sensor using a laser solder ball welding machine.

10. The processing method according to claim 6, wherein the base is manufactured by the following steps of:
providing a conductor;
placing the conductor in a mold cavity and injecting molten plastic into the mold cavity to form the base, wherein one side of the base is configured to assemble a lens holder, and the other side of the base is configured to electrically connect and mount an image sensor through the conductor.

11. (canceled)

12. A processing method of a camera module, comprising the following steps of:
providing an image acquisition module, wherein the image acquisition module comprises a base, a conductor injection-molded on the base, and an image sensor provided on one side of the base and electrically connected to the conductor; and
providing a lens holder, and connecting the lens holder to the other side of the base.

13. The processing method according to claim 12, wherein the image acquisition module is manufactured by the following steps of:
providing a base, wherein the base comprises a base body and a conductor injection-molded on the base body; and
assembling an image sensor to the base, and electrically connecting the image sensor to the conductor.

14. The processing method according to claim 13, wherein the base has a through hole, after the step of injection molding the conductor into the base and prior to the step of assembling the lens holder to the base, the processing method further comprises:
assembling a filter on the base, wherein an end of the through hole is covered by the filter, and the other opposite end of the through hole is configured to cover the image sensor.

15. The processing method according to claim 14, wherein the base has a first mounting groove and a second mounting groove, the first mounting groove is located on a side of the base and is in communication with the through hole, the first mounting groove is configured to accommodate the filter, the second mounting groove is located on the other opposite side of the base and is in communication with the through hole, and the second mounting groove is configured to accommodate the image sensor.

16. The processing method according to claim 12, wherein the image acquisition module further comprises an electronic component, wherein solder paste is injected into the base and the electronic component is electrically connected to the conductor by means of solder paste through reflow soldering, a side of the base where the image sensor is located has a second mounting groove and a third mounting groove spaced apart, the second mounting groove is configured to accommodate the image sensor, and the third mounting groove is configured to accommodate the electronic component.
